(19) United States
(12) Patent Application Publication
(10) Pub. No.: US 2013/0113104 A1
(43) Pub. Date: May 9, 2013

(54) STRUCTURE FOR PICKING UP A BURIED LAYER AND METHOD THEREOF

(71) Applicant: Shanghai Hua Hong Nec Electronics Co., Ltd., Shanghai (CN)

(72) Inventor: Wensheng Qian, Shanghai (CN)

(73) Assignee: SHANGHAI HUA HONG NEC ELECTRONICS CO., LTD., Shanghai (CN)

(21) Appl. No.: 13/670,871

(22) Filed: Nov. 7, 2012

(30) Foreign Application Priority Data
Nov. 8, 2011 (CN) 201110349910.7

(51) Int. Cl. H01L 21/762; H01L 23/498

(52) U.S. Cl. CPC H01L 21/76202; H01L 23/49827; H01L 21/76224
USPC 257/751; 438/424; 438/439

(57) ABSTRACT

A structure for picking up a buried layer is disclosed. The buried layer is formed in a substrate and has an epitaxial layer formed thereon. One or more isolation regions are formed in the epitaxial layer. The structure for picking up the buried layer includes a contact-hole electrode formed in each of the isolation regions. A bottom of the contact-hole electrode is in contact with the buried layer. As the structure of the present invention is formed in the isolation region without occupying any portion of the active region, its size is much smaller than that of a sinker region of the prior art. Therefore, device area is tremendously reduced. Moreover, as the contact-hole electrode picks up the buried layer by a metal contact, the series resistance of the device can be greatly reduced. A method of forming the above structure is also disclosed.

### CROSS-REFERENCES TO RELATED APPLICATIONS

This application claims the priority of Chinese patent application number 201110349910.7, filed on Nov. 8, 2011, the entire contents of which are incorporated herein by reference.

### TECHNICAL FIELD

The present invention relates to a structure for picking up a buried layer and method thereof.

### BACKGROUND

Buried layer process is a commonly used process in bipolar processes and high-voltage processes. As shown in FIG. 1, an existing buried layer process usually includes: forming an N-type or P-type buried layer 12 on a silicon substrate 11 through an ion implantation process; growing an epitaxial layer 13 on the buried layer; and then forming devices and circuits on the epitaxial layer 13.

Taking a bipolar transistor as an example, the buried layer 12 has two major functions: one is to isolate the epitaxial layer 13 from the substrate 11 so that different bias voltages can be applied to the substrate and the circuits formed in the epitaxial layer 13, respectively; the other is to act as an extrinsic collector region of the bipolar transistor for lowering the series resistance of the collector region to reduce the bipolar transistor's saturation voltage drop.

No matter what the role the buried layer plays, the buried layer must be picked up to an electrode in order to ground it or to apply a bias voltage on it. FIG. 1 illustrates a conventional structure for picking up a buried layer, which is formed by: forming two isolation regions 14 in an epitaxial layer 13; doping a high concentration of an impurity, which has the same type with the buried layer 12, into an active region between two isolation regions 14 to form a sinker region 15; and carrying out an annealing process for a certain period of time until the sinker region 15 contacts with the buried layer 12.

The structure for picking up the buried layer described above has four shortcomings as follows: 1) after a long-time annealing process, the buried layer diffuses a great distance both in the lateral and vertical directions, thus leading to a great parasitic capacitance between the buried layer 12 and the substrate 11; 2) although the sinker region 15 is heavily doped, it still has a great series resistance; 3) the sinker region 15 diffuses a great distance both in the lateral and vertical directions after a high-temperature annealing process for a certain period of time, which leads to the increase of device area; and 4) the long-time annealing process adopted to treat the sinker region 15 leads to a high process complexity, long cycle and high cost.

### SUMMARY OF THE INVENTION

One objective of the present invention is to provide a structure for picking up a buried layer to achieve the reduction of device area and the reduction of parasitic resistance. Another objective of the present invention is to provide a method of forming the above structure to simplify the process.

To achieve the above objectives, the present invention provides a structure for picking up a buried layer, the buried layer being formed in a substrate and having an epitaxial layer formed thereon, the epitaxial layer having one or more isolation regions formed therein, the structure for picking up a buried layer including a contact-hole electrode formed in each of the isolation regions, a bottom of the contact-hole electrode being in contact with the buried layer.

The present invention also provides a method of forming the above structure, including:

forming a doped region in a substrate by performing an ion implantation process;

growing a single crystal silicon epitaxial layer on the doped region via an epitaxial process such that the doped region becomes a buried layer;

forming one or more isolation regions in the epitaxial layer;

etching each of the isolation regions to form a hole therein, a bottom of the hole being in contact with the buried layer; and

filling a metal into the hole to form a contact-hole electrode.

As the structure of present invention is formed in each of the isolation regions without occupying any portion of the active region, its size is greatly smaller than that of the sinker region of the prior art, thus tremendously reducing the device area. Moreover, as the contact-hole electrode picks up the buried layer through a metal contact, a series resistance much smaller than that of the prior art can be achieved.

As no sinker region is needed to be formed in the structure for picking up a buried layer of the present invention, a high-temperature annealing process is no longer needed to be adopted and thus lower process cost and shorter process duration can be achieved.

### BRIEF DESCRIPTION OF THE DRAWINGS

FIG. 1 is a schematic illustration of a structure for picking up a buried layer of the prior art.

FIG. 2 is a schematic illustration of a structure for picking up a buried layer according to the present invention.

FIGS. 3a to 3d schematically illustrate a method of a structure for picking up a buried layer in steps according to the present invention.

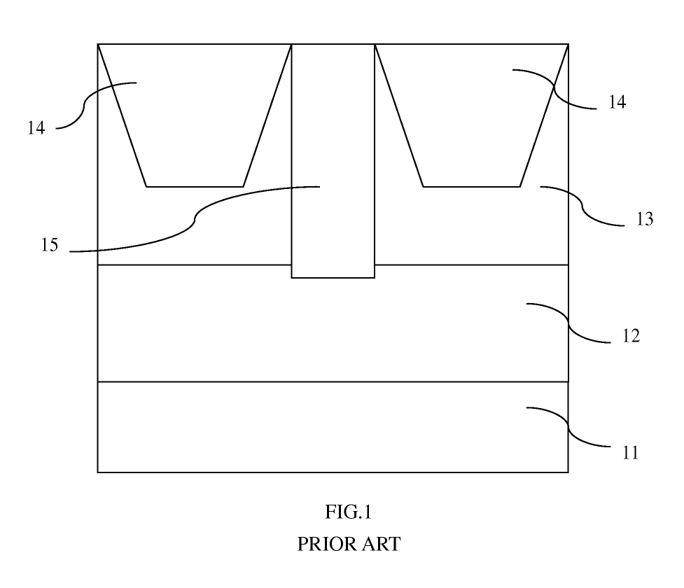

### DETAILED DESCRIPTION

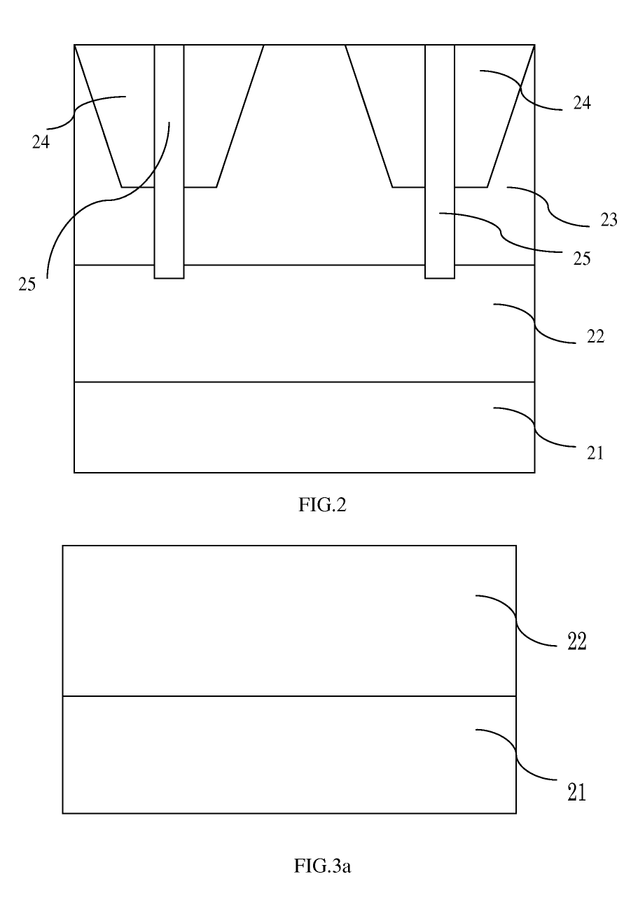

Referring to FIG. 2, the structure for picking up a buried layer of the present invention is used to pick up a buried layer 22 to the surface of a device so as to ground it or apply a bias voltage on it. The buried layer 22 is formed in a substrate 21, and an epitaxial layer 23 is formed on the buried layer 22. Isolation regions 24 are formed in the epitaxial layer 23 to isolate an active region between them. The structure for picking up a buried layer includes a contact-hole electrode 25 formed in the isolation regions 24. A bottom of the contact-hole electrode 25 is in contact with the buried layer 22.

The buried layer 22 is a heavily doped N-type or P-type buried layer having a doping concentration of 1×10¹⁸ atoms/cm³ such that good ohmic contact can be formed between the contact-hole electrode 25 and the buried layer 22.

Preferably, the contact-hole electrode 25 is formed of tungsten.

Preferably, the contact-hole electrode 25 further includes a titanium and/or titanium nitride layer at its bottom, namely, the portion in contact with the buried layer 22, to serve as a barrier layer.

The method of forming the structure for picking up a buried layer of the present invention includes the following steps:

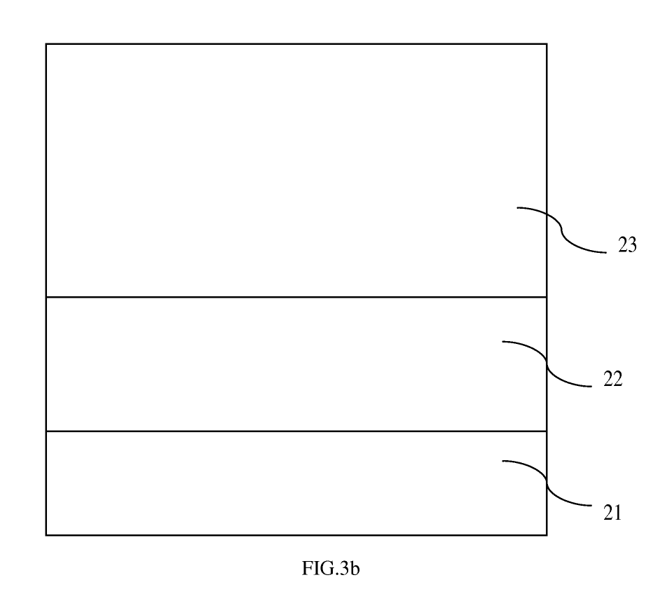

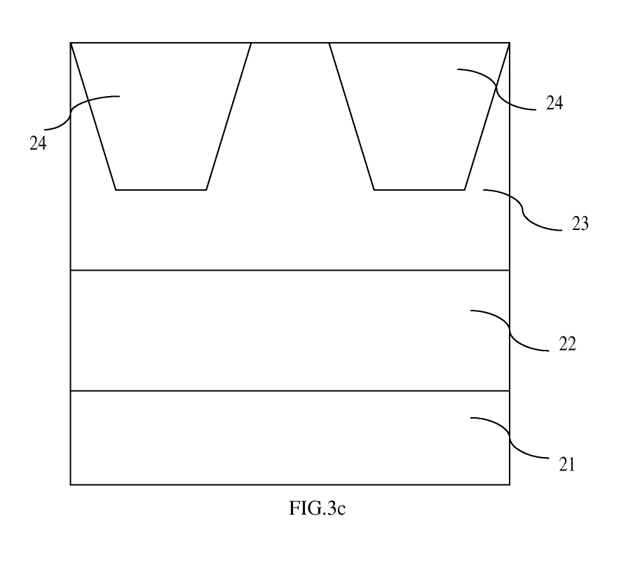

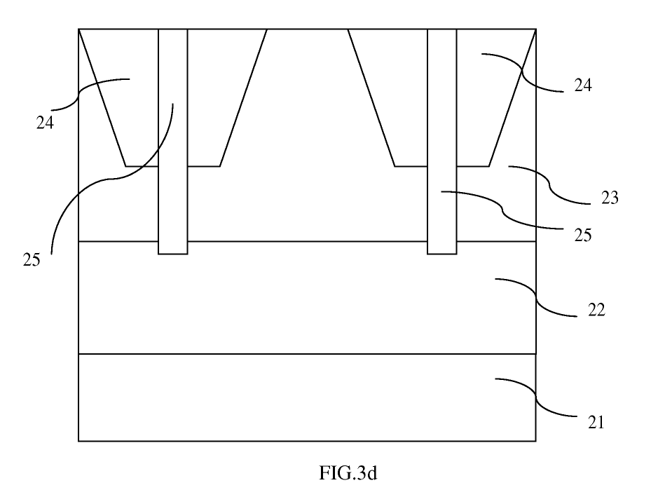

Step 1: as shown in FIG. 3a, a doped region 22 is formed by carrying out an ion implantation process to a semiconductor substrate (commonly referred to as “a silicon substrate”) 21; the doping type of the doped region 22 is opposite to the substrate 21.

Step 2: as shown in FIG. 3b, growing a single crystal silicon epitaxial layer 23 on the doped region 22 via an epitaxial process such that the doped region 22 becomes a buried layer 22; the epitaxial layer 23 has the same doping type with the substrate 21; the epitaxial process may be an in-situ doping process.

Step 3: as shown in FIG. 3c, forming isolation regions 24 in the epitaxial layer 23; the isolation regions 24 are formed of a dielectric material which is preferred to be silicon oxide; the isolation regions 24 may be formed via a local oxidation of silicon (LOCOS) process or a shallow trench isolation (STI) process.

Step 4: as shown in FIG. 3d, etching each of the isolation regions 24 to form a hole therein and filling a metal into the hole to form a contact-hole electrode 25; the bottom of the hole is in contact with the buried layer 22.

Preferably, etching the isolation region includes two steps: firstly, etching the isolation regions 24 to form a part of the hole until the bottom of the part of the hole reaches the boundary between the isolation regions 24 and the epitaxial layer 23; secondly, etching the epitaxial layer 23 to form the rest part of the hole until the surface of the buried layer 22 is exposed at the bottom of the hole. It should be appreciated that the buried layer 22 may be further etched so that the bottom of the hole is located within the buried layer 22.

Preferably, the contact-hole electrode 25 is formed of tungsten by a tungsten plug process, namely, by depositing tungsten onto a silicon wafer with a chemical vapor deposition (CVD) process to fully fill the hole with tungsten to form a tungsten plug (namely, the contact-hole electrode 25) therein, and then removing the tungsten above the surface of the silicon wafer with a dry etch back process or a chemical mechanical polishing (CMP) process.

Preferably, a titanium and/or titanium nitride barrier layer is formed over the bottom of the hole before the metal is filled into the hole to form the contact-hole electrode 25. For example, a physical vapor deposition (PVD) process is adopted first to deposit a layer of titanium onto a wafer such that a titanium pad layer is formed over the bottom and sidewalls of the hole; next, a CVD process is optionally adopted to deposit a layer of titanium nitride onto the surface of the titanium pad layer such that a titanium nitride pad layer is formed over the titanium pad layer that covers the bottom and sidewalls of the hole; and then the tungsten plug process is adopted to fill the hole with tungsten so as to form the contact-hole electrode 25.

In the structure of the present invention, as the buried layer 22 is picked up by the contact-hole electrode 25, which is located in the isolation regions 24 and penetrates through both the isolation regions 24 and the epitaxial layer 23, the present invention has advantages of a smaller device size and a smaller device-occupied area. Preferably, the contact-hole electrode 25 is formed of the metal tungsten, which has a low resistivity and a small series resistance.

Moreover, the method of forming the structure of the present invention is capable of achieving a simpler process flow by eliminating the high-temperature annealing process which is adopted by the prior art.

While preferred embodiments have been presented in the foregoing description of the invention, they are not intended to limit the invention in any way. Those skilled in the art can make various modifications and variations without departing from the spirit or scope of the invention. Thus, it is intended that the present invention embraces all such alternatives, modifications and variations of this invention.

What is claimed is:

1. A structure for picking up a buried layer, the buried layer being formed in a substrate and having an epitaxial layer formed thereon, the epitaxial layer having one or more isolation regions formed therein, the structure comprising a contact-hole electrode formed in each of the isolation regions, a bottom of the contact-hole electrode being in contact with the buried layer.

2. The structure according to claim 1, wherein the contact-hole electrode is formed of tungsten.

3. The structure according to claim 2, wherein the contact-hole electrode further comprises a titanium and/or titanium nitride barrier layer formed on its bottom.

4. The structure according to claim 1, wherein the buried layer has a doping concentration of higher than 1×10¹⁸ atoms/cm³.

5. A method of forming the structure for picking up a buried layer according to claim 1, comprising:
forming a doped region in a substrate by performing an ion implantation process;
growing a single crystal silicon epitaxial layer on the doped region via an epitaxial process such that the doped region becomes a buried layer;
forming one or more isolation regions in the epitaxial layer;
etching each of the isolation regions to form a hole therein, a bottom of the hole being in contact with the buried layer; and
filling a metal into the hole to form a contact-hole electrode.

6. The method according to claim 5, wherein each of the isolation regions is formed by using a local oxidation of silicon (LOCOS) process or a shallow trench isolation (STI) process.

7. The method according to claim 5, wherein etching each of the isolation regions to form a hole comprises:
etching the isolation region until the boundary between the isolation region and the epitaxial layer is reached; and
etching the epitaxial layer until a surface of the buried layer is exposed.

8. The method according to claim 5, wherein filling a metal into the hole comprises filling tungsten into the hole via a chemical vapor deposition (CVD) process.

9. The method according to claim 5, wherein filling a metal into the hole comprises:
forming a titanium and/or titanium nitride barrier layer over the bottom of the hole; and
filling a metal into the hole to form a contact-hole electrode therein.

10. The method according to claim 9, wherein the metal is tungsten and is filled via a CVD process.
